(19) United States
(12) Patent Application Publication
(10) Pub. No.: US 2025/0275153 A1
(43) Pub. Date: Aug. 28, 2025

(54) SEMICONDUCTOR DEVICE

(71) Applicant: SAMSUNG ELECTRONICS CO., LTD., Suwon-si (KR)

(72) Inventors: Sangbum Kim, Suwon-si (KR); Donghoon Kang, Suwon-si (KR); Minsik Yoon, Suwon-si (KR)

(73) Assignees: SAMSUNG ELECTRONICS CO., LTD., Suwon-si (KR); SEOUL NATIONAL UNIVERSITY R&DB FOUNDATION, Seoul (KR)

(21) Appl. No.: 18/826,934

(22) Filed: Sep. 6, 2024

(30) Foreign Application Priority Data
Feb. 26, 2024 (KR) 10-2024-0027406

(51) Int. Cl. H10B 63/10; G06N 3/04; G06N 3/063

(52) U.S. Cl. CPC H10B 63/10; G06N 3/04; G06N 3/063

(57) ABSTRACT

A semiconductor device includes a plurality of horizontal electrode layers stacked in a first direction perpendicular to an upper surface of a substrate; a plurality of vertical structures extending in the first direction, penetrating the plurality of horizontal electrode layers and arranged in a second direction and a third direction parallel to the upper surface of the substrate and intersecting each other; and a plurality of bitlines connected to the plurality of vertical structures in the first direction, wherein each of the plurality of vertical structures includes a vertical electrode layer having a pillar shape extending in the first direction, and a phase change material layer extending in the first direction and disposed between the vertical electrode layer and the plurality of horizontal electrode layers in the second direction and the third direction.

### CROSS-REFERENCE TO RELATED APPLICATION(S)

This application claims benefit of priority to Korean Patent Application No. 10-2024-0027406 filed on Feb. 26, 2024 in the Korean Intellectual Property Office, the disclosure of which is herein incorporated by reference in its entirety.

### BACKGROUND

One or more example embodiments of the disclosure relate to a semiconductor device.

As the field of an application of artificial intelligence-related technology expands, research into a semiconductor device to implement trained neural networks in hardware has been also actively conducted. A neural network may include a plurality of nodes divided into a plurality of layers, and a weight determined in training may be assigned to a connection path connecting at least a portion of a plurality of nodes to each other. A variety of semiconductor devices implementing neural networks in hardware by storing weights determined through training in memory cells has been suggested, but complex peripheral circuits may be necessary to actually execute neuromorphic operations based on neural networks.

### SUMMARY

One or more example embodiments of the disclosure provide a semiconductor device which may process neuromorphic computation based on a neural network without a need for a complex peripheral circuit.

According to one or more example embodiments, a semiconductor device comprises a plurality of horizontal electrode layers stacked in a first direction perpendicular to an upper surface of a substrate; a plurality of vertical structures extending in the first direction, penetrating the plurality of horizontal electrode layers and arranged in a second direction and a third direction, the second direction and the third direction parallel to the upper surface of the substrate and intersecting each other; and a plurality of bitlines electrically connected to the plurality of vertical structures in the first direction, wherein each of the plurality of vertical structures includes a vertical electrode layer having a pillar shape extending in the first direction, and a phase change material layer extending in the first direction and disposed between the vertical electrode layer and the plurality of horizontal electrode layers in the second direction and the third direction.

According to one or more example embodiments, a semiconductor device comprises a plurality of cell regions each including a plurality of memory cells, the plurality of memory cells being arranged in a first direction perpendicular to an upper surface of a substrate, and arranged in a second direction and a third direction, the second direction and the third direction being parallel to the upper surface of the substrate and intersecting each other, the plurality of memory cells being disposed in different positions in at least one of the second direction or the third direction; and at least one connection region disposed between the plurality of cell regions, wherein each of the plurality of cell regions includes a plurality of cell electrode layers stacked in the first direction, and a plurality of vertical structures extending in the first direction and penetrating the plurality of cell electrode layers, each of the plurality of vertical structures including a vertical electrode layer and a phase change material layer surrounding the vertical electrode layer, and wherein a connection region of the at least one connection region includes a plurality of connection electrode layers stacked in the first direction and electrically connected to the plurality of cell electrode layers, and a plurality of pillar structures extending in the first direction and penetrating the plurality of connection electrode layers, each of the plurality of pillar structures including a bias electrode layer and a switching material layer surrounding the bias electrode layer.

According to one or more example embodiments, a semiconductor device supporting computation based on a neural network including a plurality of layers comprises a memory cell array including a plurality of cell regions, wherein each of the plurality of cell regions include a plurality of memory cells formed on a substrate; and a peripheral circuit including a voltage input circuit and a voltage detector circuit, the voltage input circuit being configured to input an input voltage corresponding to input data of the neural network to the memory cell array, and the voltage detector circuit being configured to read an output voltage corresponding to output data of the neural network from the memory cell array, wherein, in the neural network, weights corresponding to connection paths connecting first nodes of a first layer and second nodes of a second layer, are stored in the plurality of memory cells disposed in a first cell region among the plurality of cell regions, wherein the first layer and the second layer are disposed consecutively, wherein input voltages corresponding to data of the first nodes are input to the first cell region through first lines electrically connected to the first cell region, and output voltages corresponding to data of the second nodes are transferred to a second cell region adjacent to the first cell region through second lines electrically connected to the first cell region, and wherein the first lines and the second lines extend in different directions.

According to one or more example embodiments, a method of manufacturing a semiconductor device comprises alternately stacking a plurality of insulating layers and a plurality of horizontal electrode layers on a substrate, forming a plurality of holes penetrating the plurality of horizontal electrode layers in a first direction perpendicular to an upper surface of the substrate, forming a phase change material layer and a vertical electrode layer in order in an internal space of each of the plurality of holes, forming a staircase structure by etching at least a portion of the plurality of horizontal electrode layers and the plurality of insulating layers in a second direction parallel to the upper surface of the substrate, forming a plurality of isolation layers dividing the plurality of insulating layers and the plurality of horizontal electrode layers into a plurality of blocks in a third direction intersecting the second direction and parallel to the upper surface of the substrate, and forming a plurality of conductive lines electrically connected to the vertical electrode layer and extending in the third direction.

### BRIEF DESCRIPTION OF DRAWINGS

The above and other aspects, features, and advantages in the example embodiment will be more clearly understood from the following detailed description, taken in combination with the accompanying drawings, in which:

FIGS. 1 and 2 are diagrams illustrating a neural network implemented by a semiconductor device according to one or more example embodiments of the disclosure;

FIGS. 3 and 4 are diagrams illustrating a semiconductor device according to one or more example embodiments of the disclosure;

FIG. 5 is a diagram illustrating operations of a semiconductor device according to one or more example embodiments of the disclosure;

FIGS. 6 and 7 are diagrams illustrating a semiconductor device according to one or more example embodiments of the disclosure;

FIG. 8 is a diagram illustrating a neural network implemented by a semiconductor device according to one or more example embodiments of the disclosure;

FIGS. 9 to 14 are diagrams illustrating a semiconductor device according to one or more example embodiments of the disclosure;

FIG. 15 is a diagram illustrating a semiconductor device according to one or more example embodiments of the disclosure;

FIG. 16 is a diagram illustrating a semiconductor device according to one or more example embodiments of the disclosure;

FIGS. 17 to 19 are diagrams illustrating a semiconductor device according to one or more example embodiments of the disclosure; and

FIGS. 20 to 33 are diagrams illustrating a method of manufacturing a semiconductor device according to one or more example embodiments of the disclosure.

### DETAILED DESCRIPTION

Hereinafter, some example embodiments will be described as follows with reference to the accompanying drawings.

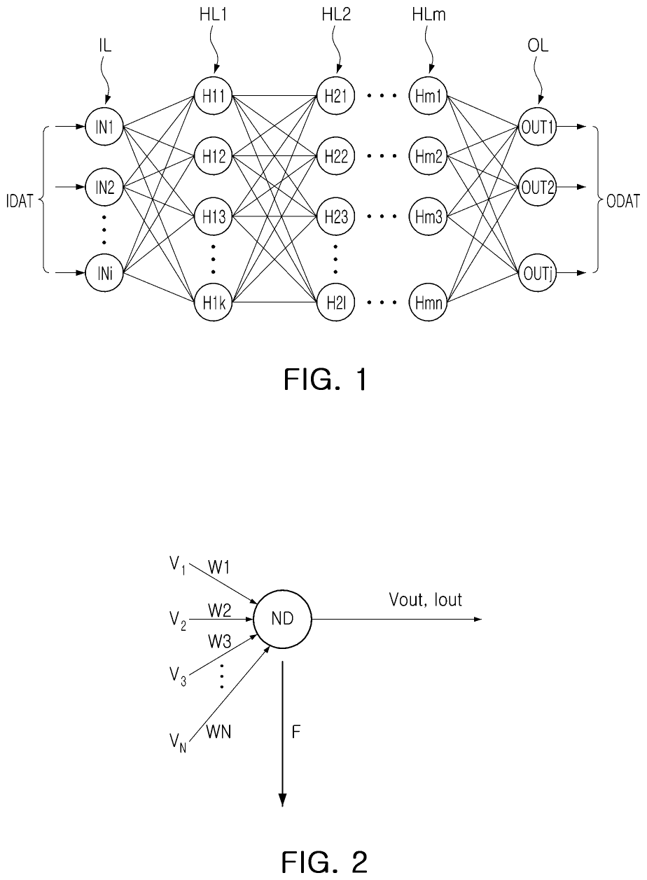

FIGS. 1 and 2 are diagrams illustrating a neural network implemented by a semiconductor device according to one or more example embodiments.

A semiconductor device according to one or more example embodiments may implement neuromorphic computation based on a neural network in an analog manner. FIGS. 1 and 2 are diagrams illustrating a neural network implemented by a semiconductor device according to one or more example embodiments.

Referring to FIG. 1, the neural network may include an input layer IL, a plurality of hidden layers HL1 to HLm and an output layer OL. The input layer IL may include an I number of input nodes IN1 to INi (where i is a natural number), and for example, input data IDAT in a form of a vector having a length of i may be input to each input node.

The input data IDAT may be input to a hidden layer including an m number of hidden layers HL1 to HLm (where m is a natural number), and each hidden layer HL1 to HLm may include hidden nodes. For example, a first hidden layer HL1 may include a k number of hidden nodes H11 to H1k (where k is a natural number), and an mth hidden layer HLm may include an n number of hidden nodes hm1 to hmn.

In one or more example embodiments illustrated in FIG. 1, the number of hidden nodes included in each hidden layer HL1 to HLm may be determined in various manners. For example, at least a portion of the hidden layers HL1 to HLm may include the same number of hidden nodes, and at least the other portion of the hidden layers HL1 to HLm may include a different number of hidden nodes.

The output layer OL may include a j number of output nodes OUT1 to OUTj (where j is a natural number). For example, the output layer OL may output results (for example, scores or class scores) for each class for the input data IDAT as output data ODAT.

The neural network illustrated in FIG. 1 may include a connection path between nodes illustrated as a linear line between two nodes, and a weight used in each connection path. Nodes included in one of the hidden layers HL1 to HLm may not be connected to each other, and nodes included in different layers may be completely or partially connected to each other.

In a neural network according to one or more example embodiments illustrated in FIG. 1, nodes may be completely connected to each other. In a semiconductor device implementing the neural network in FIG. 1 according to one or more example embodiments, a value of each node may appear in a form of a voltage, and the voltage of each node may be determined by equilibrium propagation. For example, each node may apply a nonlinear function such that the voltage determined by equilibrium propagation may have nonlinear properties.

Each node may perform computation by receiving an output of a previous node(s) and may output a result of computation to a subsequent node(s). In this case, each node may calculate a value to be output by applying an input value to a specific function, for example, a nonlinear function.

In one or more example embodiments, weights given to connection paths connecting nodes included in a neural network may be determined using a data set for which a correct answer is already known. The data set used to determine weights may be training data, and a training task for adjusting weights given to the connection paths between nodes in the neural network may be performed using training data.

FIG. 2 is a diagram illustrating one or more example embodiments of computation performed at node ND, one of nodes included in a neural network of the same type as in the example embodiment described with reference to FIG. 1. Referring to FIG. 2, an N number of inputs input to a node ND may correspond to an N number of voltages V1 to VN in a semiconductor device according to one or more example embodiments. An N number of weights W1 to WN reflected in the N number of inputs may be matched with resistor values of memory cells. An output value of a node ND may be determined by the N number of voltages V1 to VN, the resistor values of memory cells, and an element functioning as a specific function F exhibiting a non-linear current.

The neural network as described with reference to FIG. 1 may be applied to fields in which artificial intelligence is used. To implement a neural network in hardware, a semiconductor device including memory cells may be used, and the memory cells may store weights given to the connection paths connecting nodes of the hidden layers HL1 to HLm to each other.

However, to store weights in the memory cells and to implement neuromorphic computation with the stored weights, complex circuits including an analog-to-digital converter, and a digital-to-analog converter may need to be included in the peripheral circuit controlling the memory cells. In one or more example embodiments, a semiconductor device which may perform training and inference of a neural network using an energy-based model may be provided, and accordingly, a peripheral circuit may be implemented relatively in a simplified manner.

Energy of a neural network may be represented by a predetermined function. Equation 1 below may represent an example of network energy based on a hopfield network.

$$E ( s , ρ ( s ) , θ = \{ W , b ) ) := \frac{1}{2} {\sum }_{i} {s}_{i} - \frac{1}{2} {W}_{ij} ρ ( {s}_{i} ) ρ ( {s}_{i} ) - {\sum }_{i} {b}_{i} ρ ( {s}_{i} ) \qquad [ Equation 1 ]$$

In [Equation 1], W indicates a weight corresponding to an entirety of connections included in a layer, and may be represented in a form of a two-dimensional matrix. S denotes a state of each node, p denotes an activation function, and a form of energy and an activation function may be represented in various manners.

“Equilibrium” may assume a network with minimum energy, and may indicate a state of each node converging to a point at which the energy is minimum. Various energy model-based learning algorithms, including “equilibrium propagation,” may require computation to find an equilibrium point to perform an inference, which is a process of finding a correct answer to a given input. The semiconductor device according to one or more example embodiments may implement inference computation of an energy-based model without a complicated peripheral circuit using a three-dimensional disposed memory cell array and a switch element integrated therewith. Each memory cell included in the memory cell array may be implemented as a memristor.

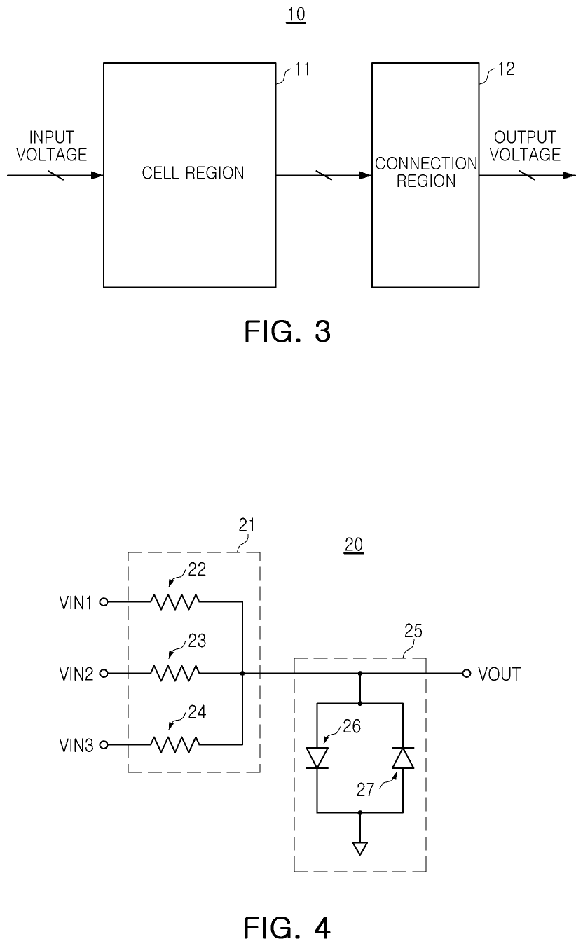

FIGS. 3 and 4 are diagrams illustrating a semiconductor device according to one or more example embodiments.

FIG. 3 is a diagram illustrating a method of implementing computation of each hidden layer included in a neural network. Referring to FIG. 3, a hidden layer 10 may be physically implemented by a cell region 11 and a connection region 12 of the semiconductor device.

When an input voltage corresponding to input data is applied to a cell region 11, a weight given to each connection path through which each piece of input data is transferred may be reflected in the input voltage in accordance with Kirchhoff's law. The connection region 12 may include connection cells having a structure different from that of memory cells, and a level of a voltage generated by reflecting the weight of the input voltage in the cell region 11 may be clipped by the connection cells.

For example, the cell region 11 may include memory cells disposed in a three-dimensional form, and the memory cells may be connected to first lines and second lines. When an input voltage corresponding to input data is applied to one of first lines and second lines, for example, first lines, energy equilibrium may occur according to Kirchhoff's law, and an output voltage corresponding to output data may be applied to the second lines.

A resistance of each memory cell may be adjusted by a voltage applied through the first lines and the second lines, and a weight may be reflected as a resistor value in each memory cell. In one or more example embodiments, to adjust a resistance of each memory cell, each memory cell may include a first electrode layer connected to the first line, a second electrode layer connected to the second line, and a phase change material layer disposed between the first electrode layer and the second electrode layer. Each connection cell may be implemented as an element having diode-like properties, and in one or more example embodiments, each connection cell may include a pair of electrode layers and a switching material layer disposed therebetween.

FIG. 4 is a diagram illustrating an example of an analog circuit diagram for implementing each hidden layer included in a neural network. Referring to FIG. 4, an analog circuit 20 may include a first analog circuit 21 configured to receive input voltages VIN1 to VIN3 corresponding to input data, and a second analog circuit 25 configured to adjust an output of the first analog circuit 21. A first input voltage VIN1 may correspond to first input data, a second input voltage VIN2 may correspond to second input data, and a third input voltage VIN3 may correspond to third input data.

The first analog circuit 21 may include a plurality of programmable resistor elements 22 to 24. A resistor value of each of the plurality of resistor elements 22 to 24 may be adjusted during a training process of the neural network, and in one or more example embodiments, the plurality of resistor elements 22 to 24 may be physically implemented by memory cells included in the semiconductor device. The first resistor element 22 may have a resistor value corresponding to a first weight reflected in the first input data, the second resistor element 23 may have a resistor value corresponding to a second weight reflected in the second input data, and the third resistance element 24 may have a resistor value corresponding to a third weight reflected in the third input data.

The second analog circuit 25 may include a first diode 26 and a second diode 27, and the first diode 26 and the second diode 27 may be physically implemented by connection cells included in the semiconductor device. For example, by the first and second diodes 26 and 27, the second analog circuit 25 may implement an activation layer configured to provide an activation function based on a sigmoid nonlinearity function.

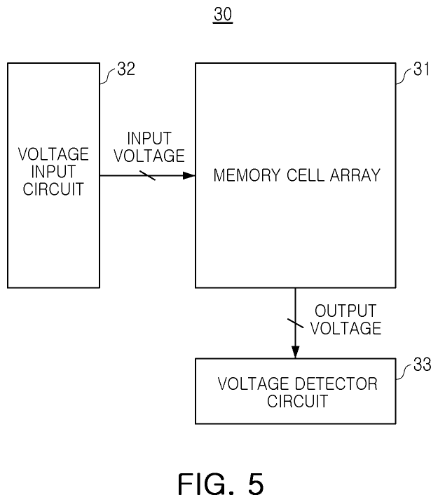

FIGS. 5 to 7 are diagrams illustrating operations of a semiconductor device according to one or more example embodiments.

Referring to FIG. 5, a semiconductor device 30 according to one or more example embodiments may include a memory cell array 31, a voltage input circuit 32, and a voltage detector circuit 33. In the memory cell array 31, a plurality of memory cells may be disposed in a three-dimensional structure, and weights given to connection paths of nodes in a neural network may be stored in the plurality of memory cells. The voltage input circuit 32 and the voltage detector circuit 33 may be included in a peripheral circuit. The voltage input circuit 32 may input an input voltage corresponding to input data of a neural network to the memory cell array 31, and the voltage detector circuit 33 may detect an output voltage corresponding to output data of the neural network.

The memory cell array 31 may include a plurality of cell regions, and two or more memory cells may be disposed in each of the plurality of cell regions. Each of the plurality of cell regions may correspond to the first analog circuit 21 described with reference to FIG. 4. A connection region may be disposed between the plurality of cell regions, and the connection region may correspond to the activation layer implemented by the second analog circuit 25 described with reference to FIG. 4. Each memory cell may have a variable resistive property, and a weight to be reflected in the input data in the first analog circuit may be stored in the cell regions by adjusting a resistor value of each memory cell. Each connection cell may have a diode property.

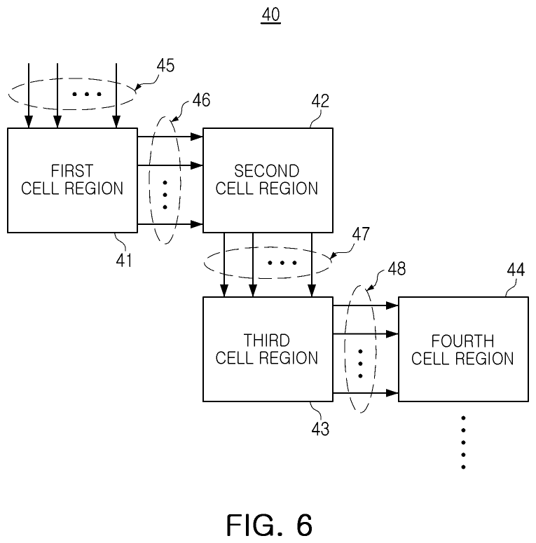

As illustrated in FIG. 6, a memory cell array 40 may include a plurality of cell regions 41 to 44, and the plurality of cell regions 41 to 44 may be connected to each other to have the same structure as that of the plurality of hidden layers included in the neural network. A first cell region 41 corresponding to a first hidden layer may receive an input voltage corresponding to input data of the neural network through first lines 45 and may be connected to a second cell region 42 through second lines 46. The first lines 45 may be connected to the voltage input circuit 32 according to one or more example embodiments illustrated in FIG. 5. For example, memory cells included in the first cell region 41 may be connected to the first lines 45 and the second lines 46.

Between the first cell region 41 and the second cell region 42, a plurality of connection cells may be connected to the second lines 46, and the plurality of connection cells may provide a second analog circuit implementing a nonlinear function. The second cell region 42 may store weights assigned to connection paths between the first hidden layer and a second hidden layer, and may be connected to a third cell region 43 through third lines 47. The third cell region 43 may store weights assigned to the connection paths between the second hidden layer and a third hidden layer, and may be connected to a fourth cell region 44 through fourth lines 48. The third lines 47 and the fourth lines 48 may also be connected to connection cells to provide an activation layer.

When an input voltage for a training task or an inference task of the neural network is input to the first lines 45 by the voltage input circuit, an output voltage may be determined by equilibrium propagation and detected by the voltage detector circuit through lines connected to memory cells of a last cell region. In the training task, the output voltage detected by the voltage detector circuit may be compared with the output data of the training data, and a resistor value of at least one of memory cells included in the cell regions 41 to 44 may be adjusted based on a result of comparison. A resistor value of each memory cell may be adjusted by varying the voltage input to the lines 45 to 48 connected to the cell regions 41 to 44.

In the inference task, the output voltage detected by the voltage detector circuit may be confirmed as a result of inference computation. Accordingly, in one or more example embodiments, a semiconductor device may be implemented by using a simple peripheral circuit including a circuit for inputting a voltage to the cell regions 41 to 44 and a circuit for detecting a voltage from the cell regions 41 to 44. Also, since the training task and the inference task may be performed swiftly using equilibrium propagation, an efficiency and an operation speed of the semiconductor device supporting neuromorphic computation may be improved and power consumption may be reduced.

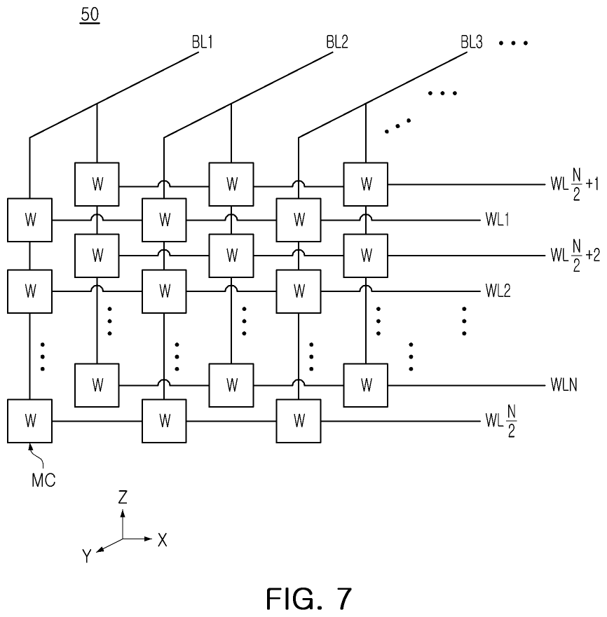

FIG. 7 is a diagram illustrating an example structure of a cell region included in a semiconductor device according to one or more example embodiments. Referring to FIG. 7, a cell region 50 may include a plurality of memory cells MC, and each of the plurality of memory cells MC may store a weight W assigned to a connection path between a pair of nodes in a neural network. A portion of the plurality of memory cells may be connected to each other in a first direction (e.g., Z-axis direction) to provide a memory cell string.

As illustrated in FIG. 7, the plurality of memory cell strings may be connected to a plurality of wordlines WL1 to WLN extending in a second direction (e.g., X-axis direction) and a plurality of bitlines extending in a third direction (e.g., Y-axis direction) BL1 to BLM. For example, the first direction may be perpendicular to an upper surface of a substrate, and the second and third directions may be parallel to the upper surface of the substrate and intersecting each other. Memory cells MC may be disposed at points at which the plurality of bitlines BL1 to BLM and the plurality of wordlines WL1 to WLN intersect each other.

In one or more example embodiments, when the cell region 50 matches the first hidden layer directly connected to an input layer in the neural network, weights W corresponding to connection paths connecting input nodes included in the input layer to hidden nodes included in the first hidden layer may be stored in the memory cells MC. In a training task for a neural network, and an inference task performing neuromorphic computation using a neural network, when input voltages corresponding to the input data input to the input nodes are applied to the plurality of bitlines BL1 to BL3, voltages of the plurality of wordlines WL1 to WLN may be changed to an output voltage corresponding to output values of hidden nodes. In example embodiments, input voltages may be applied to the plurality of wordlines WL1 to WLN, and an output voltage may be output to the plurality of bitlines BL1 to BLM.

The cell region 50 may be disposed adjacent to another cell region in the second direction, and the another cell region may correspond to the second hidden layer directly connected to the first hidden layer in the neural network. The plurality of wordlines WL1 to WLN may be shared with other adjacent cell regions in the second direction, and an output voltage corresponding to an output value of the first hidden layer may be transferred to other cell regions through the plurality of wordlines WL1 to WLN. As such, in one or more example embodiments, neuromorphic computation based on the neural network may be performed using the equilibrium propagation occurring in the semiconductor device after applying an input voltage to the bitlines BL1 to BLM corresponding to the input nodes.

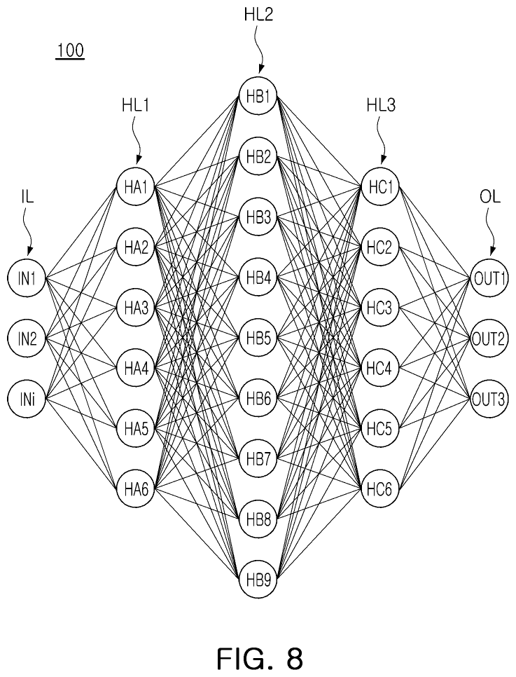

FIG. 8 is a diagram illustrating a neural network implemented by a semiconductor device according to one or more example embodiments.

In the example embodiment illustrated in FIG. 8, a neural network 100 may include an input layer IL, an output layer OL, and hidden layers HL1 to HL3 disposed therebetween. The neural network 100 according to one or more example embodiments illustrated in FIG. 8 may include the first to third hidden layers HL1 to HL3, but the number of hidden layers HL1 to HL3 in example embodiments may be varied.

Referring to FIG. 8, the first hidden layer HL1 may include six hidden nodes HA1 to HA6, the second hidden layer HL2 may include nine hidden nodes HB1-HB9, and the third hidden layer HL3 may include sixth hidden nodes HC1 to HC6. However, the number of hidden nodes included in each of the hidden layers HL1 to HL3 may also be varied in example embodiments.

In the neural network 100, weights may be assigned to connection paths between nodes directly connected to each other. Before the neural network 100 is trained, weights may be determined arbitrarily, and the weights assigned to the connection paths may be adjusted by training the neural network using training data given as input data and output data.

In the example embodiment illustrated in FIG. 8, the input nodes IN1 to IN3 may be connected to hidden nodes HA1 to HA6 of the first hidden layer HL1 along six connection paths. 18 weights may be respectively assigned to 18 connection paths connecting the input layer IL to the first hidden layer HL1. Similarly, 54 weights may be respectively assigned to each of 54 connection paths connecting the first hidden layer HL1 to the second hidden layer HL2, and 54 weights may be assigned to 54 connection paths connecting the second hidden layer HL2 to the third hidden layer HL3, respectively. Also, 18 weights may be assigned to 18 connection paths connecting the third hidden layer HL3 to the output layer OL, respectively.

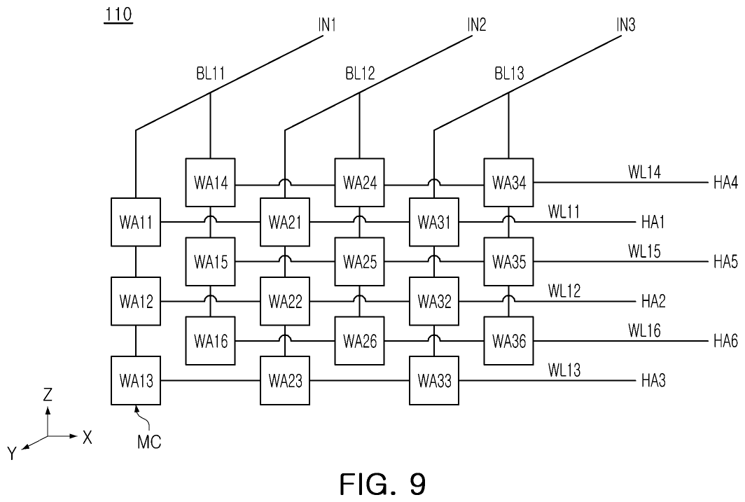

Hereinafter, with reference to FIGS. 9 to 14, a semiconductor device for implementing neuromorphic computation based on the neural network 100 according to one or more example embodiments illustrated in FIG. 8 will be described in detail.

FIGS. 9 to 14 are diagrams illustrating a semiconductor device according to one or more example embodiments.

The operation of the semiconductor device described with reference to FIGS. 9 to 14 may be based on an energy-based model. Output data may be determined by applying an input voltage corresponding to input data to bitlines BL11 to BL13 connected to a first cell region 110, and by detecting the output voltage at bitlines BL31 to BL33 connected to a fourth cell region 150 after a relatively short period of time during which equilibrium propagation is completed. For example, when an input voltage is applied to the bitlines BL11 to BL13 connected to the first cell region 110, by equilibrium propagation, voltages of wordlines WL11 to WL16 and WL21 to WL26 and bitlines BL21 to BL29 and BL31 to BL33 may be adjusted to a specific level almost simultaneously.

For example, when an input voltage is applied to the bitlines BL11 to BL13 connected to the first cell region 110, the voltages of the wordlines WL11 to WL16 connecting the first cell region 110 to the second cell region 130 may be applied to the first hidden layer HL1. A voltage corresponding to an output value of each of the included hidden nodes HA1 to HA6 may be adjusted. Also, voltages of the bitline BL21 to BL29 connecting the second cell region 130 to the third cell region 140 may be adjusted to a voltage corresponding to an output value of each of the hidden nodes HB1 to HB9 included in the second hidden layer HL2.

A voltage of each of the wordlines WL21 to WL26 connecting the third cell region 140 to the fourth cell region 150 may be adjusted to a voltage corresponding to an output value of each of the hidden nodes HC1-HC6 included in the third hidden layer HL3. The voltage of each of the bitlines BL31 to BL33 connected to the fourth cell region 150 may be adjusted to the voltage corresponding to the output data. Since the voltage of each bitline BL31 to BL33 is adjusted to the voltage corresponding to the output data by equilibrium propagation in a relatively short period of time, the time required for a training task and an inference task of the neural network may be shortened.

FIG. 9 is a diagram illustrating a first cell region 110 included in a semiconductor device according to one or more example embodiments. The first cell region 110 may include a plurality of memory cells MC, and a portion of the plurality of memory cells MC may be connected to each other in the first direction (e.g., Z-axis direction) and may provide a memory cell string. The plurality of memory cells MC may be disposed at intersections of the plurality of wordlines WL11 to WL16 extending in the second direction (e.g., X-axis direction) and the plurality of bitlines BL11 to BL13 extending in the third direction (e.g., Y-axis direction).

In one or more example embodiments, each of the plurality of memory cells MC may include a pair of electrode layers and a phase change material layer disposed therebetween. One electrode layer of a pair of electrode layers may be connected to one of the plurality of bitlines BL11 to BL13, and the other electrode layer of the pair may be connected to one of the plurality of wordlines WL11 to WL16. In one or more example embodiments, the pair of electrode layers may include a cell electrode layer extending in the second direction and a vertical electrode layer extending in the third direction, and the cell electrode layer may be connected to one of the plurality of wordlines WL11 to WL16, and the vertical electrode layer may be connected to one of the plurality of bitlines BL11 to BL13.

In the memory cells MC of the first cell region 110, 18 weights WA11-WA16, WA21-26, WA31-WA36 assigned to connection paths connecting the input layer IL to the first hidden layer HL1 may be stored. For example, the memory cells MC and the weights WA11-WA16, WA21-26, WA31-WA36 may be matched respectively, and accordingly, one of 18 weights WA11-WA16, WA21-26, WA31-WA36 may be stored in one of the memory cells MC.

The plurality of bitlines BL11 to BL13 may correspond to input nodes IN1 to IN3 of the neural network 100. The plurality of bitlines BL11 to BL13 may be connected to a voltage input circuit disposed on the peripheral circuit of the semiconductor device, and input voltages corresponding to the input data of the neural network 100 may be applied to the plurality of bitlines BL11 to BL13.

For example, the first input voltage corresponding to the input data input to the first input node IN1 may be applied to the first bitline BL11. Six weights WA11 to WA16 assigned to the six connection paths connected to the first input node IN1 may be stored in the sixth memory cells MC connected to the first bitline BL11.

A second input voltage corresponding to the input data input to the second input node IN2 may be applied to the second bitline BL12. Six weights WA21 to WA26 assigned to the 6 connection paths connected to the second input node IN2 may be stored in the six memory cells MC connected to the second bitline BL12. Similarly, six weights WA31 to WA36 stored in the six memory cells connected to a third bitline BL13 may be assigned to the six connection paths connected to the third input node IN3.

Three memory cells MC may be connected to each of the plurality of wordlines WL11 to WL16, and the plurality of wordlines WL11 to WL16 may correspond to six hidden nodes HA1 to HA6 included in the first hidden layer HL1 of the neural network 100. For example, the first wordline WL11 may correspond to a first hidden node HA1, the second wordline WL12 may correspond to a second hidden node HA2, and the third wordline WL13 may correspond to a third hidden node HA3. The fourth wordline WL14 may correspond to a fourth hidden node HA4, the fifth wordline WL15 may correspond to a fifth hidden node HA5, and the sixth wordline WL16 may correspond to a sixth hidden node HA6.

For example, the weights WA11, WA12, and WA13 assigned to the three connection paths connecting the first hidden node HA1 to the three input nodes IN1 to IN3 may be stored in each of the three memory cells MC connected to the first wordline WL11. Accordingly, the voltage of first wordline WL11 may be adjusted to an equilibrium point by equilibrium propagation, without separate control operation, based on the input voltages VIN1 to VIN3 applied to the bitlines BL11 to BL13.

As described with reference to FIG. 2, the output value of the node included in the neural network may be consequently determined by applying a predetermined nonlinear function to results of computation of output values and weights of the nodes directly connected to the node. The semiconductor device according to one or more example embodiments may include a connection region in which connection cells implementing an analog nonlinear function are disposed. Connection cells may be disposed between a pair of connection regions arranged in the second or third direction.

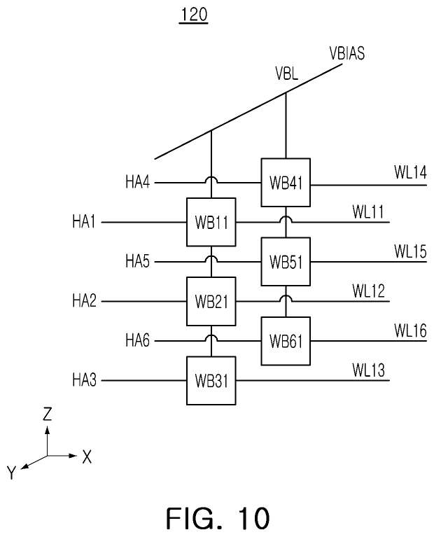

For example, a first connection region 120 connected to the first cell region 110 may be implemented as in one or more example embodiments illustrated in FIG. 10. Referring to FIG. 10, six connection cells DC11 to DC16 corresponding to six hidden nodes HA1 to HA6 included in the first hidden layer HL1 of the neural network 100 may be disposed in the first connection region 120. The six connection cells DC11 to DC16 may be commonly connected to a bias line VBL and may be connected to six wordlines WL11 to WL16, respectively. The six connection cells DC11 to DC16 may be disposed in the same position in the second direction.

For example, the connection cell DC11 connected to the first wordline WL11 may be connected to the first wordline WL11 extending from the first cell region 110. Accordingly, when input voltages VIN1 to VIN3 are input to the bitlines BL11 to BL13, the voltage of the first wordline WL11 may be adjusted to a voltage clipped by the connection cell DC11. The voltage of the first wordline WL11 may be adjusted to a voltage corresponding to an output value of the first hidden node HA1.

The structure of each of the connection cells DC11 to DC16 may be similar to the structure of the memory cells MC. However, while the memory cells MC including a phase change material layer has a variable resistance property to store weight as a resistor value, the connection cells DC11 to DC16 may include a switching material layer to have a property as a switching element.

For example, each of the connection cells DC11 to DC16 may include a pair of electrode layers and a switching material layer disposed therebetween, one electrode layer of the pair of electrode layers may be a connection electrode layer extending in the second direction, and the other electrode layer of the pair may be a bias electrode layer extending in the third direction. The bias electrode layer may receive a predetermined bias voltage (VBIAS) through the bias line VBL. The connection electrode layer may extend in the second direction and may be physically and/or electrically connected to the cell electrode layer of the first cell region 110.

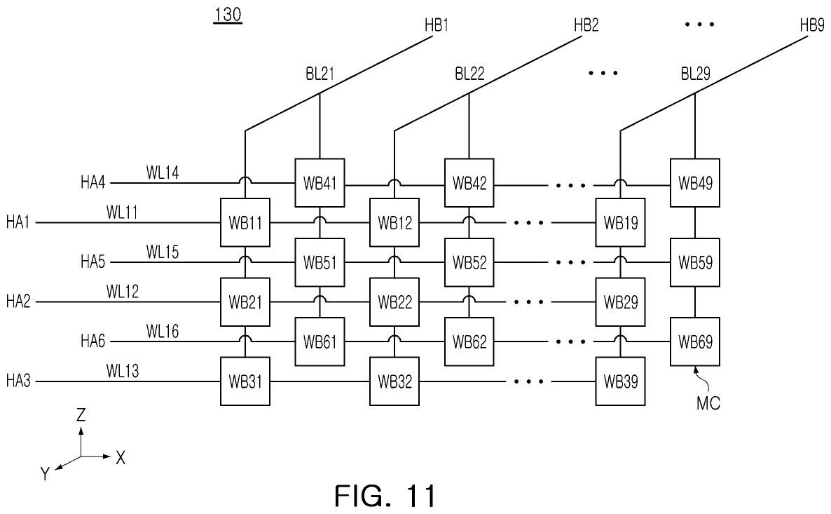

FIG. 11 is a diagram illustrating a second cell region 130 included in a semiconductor device according to one or more example embodiments. The second cell region 130 may include a plurality of memory cells MC, and the arrangement form of the plurality of memory cells MC may be similar to that of the first cell region 110. A portion of the plurality of memory cells MC may be connected to each other in the first direction (e.g., Z-axis direction) and may provide a memory cell string, and the plurality of memory cells MC may be disposed at intersections of the plurality of wordlines WL11 to WL16 extending in the second direction (e.g., X-axis direction) and the plurality of bitlines BL21 to BL29 extending in the third direction (e.g., Y-axis direction).

Each of the plurality of memory cells MC may include a pair of electrode layers and a phase change material layer disposed therebetween. The cell electrode layer, which is one of the pair of electrode layers, may be connected to one of the plurality of wordlines WL11 to WL16, and the vertical electrode layer, the other of the pair of electrode layers, may be connected to one of the plurality of bitlines BL11 to BL13.

54 weights WB11 to WB19, WB21 to WB29, WB31 to WB39, WB41 to WB49, WB51 to WB59, and WB61 to WB69 assigned to connection paths connecting the first hidden layer HL1 to the second hidden layer HL2 may be stored in the memory cells MC of the second cell region 130. For example, memory cells MC and weights WB11 to WB69 may be matched with each other respectively, such that one of 54 weights WB11 to WB69 may be stored in a corresponding memory cell MC.

As described with reference to FIGS. 9 and 10, the voltage of each of the plurality of wordlines WL11 to WL16 may be adjusted to a voltage corresponding to output values of the six hidden nodes HA1 to HA6 included in the first hidden layer HL1 by equilibrium propagation. Accordingly, an operation of inputting the output values of the hidden nodes HA1 to HA6 of the first hidden layer HL1 to the connection paths connecting the first hidden layer HL1 to the second hidden layer HL2 may be implemented by adjusting the voltage of each of the plurality of wordlines WL11 to WL16 by equilibrium propagation.

Nine weights WB11 to WB19 assigned to nine connection paths connected to the first hidden node HA1 of the first hidden layer HL1 may be stored in nine memory cells MC connected to the first wordline WL11. Nine weights WB21 to WB29 assigned to nine connection paths connected to the second hidden node HA2 of the first hidden layer HL1 may be stored in the nine memory cells MC connected to the second wordline WL12. Similarly, nine weights WB31 to WB39 assigned to nine connection paths connected to the third hidden node HA3 of the first hidden layer HL1 may be stored in the nine memory cells connected to the third wordline WL13. The weights stored in the memory cells MC connected to the other wordlines WL14 to WL16 may also be understood by referring to the description above.

Six memory cells MC may be connected to each of the plurality of bitlines BL21 to BL29, and the plurality of bitlines BL21 to 29 may correspond to nine hidden nodes HB1-HB9 included in the second hidden layer HL2 of the neural network 100. The weights WB11, WB21, WB31, WB41, WB51, and WB61 assigned to the six connection paths connecting the first hidden node HB1 of the second hidden layer HL2 to the hidden nodes HA1 to HA6 of the first hidden layer HL1 may be stored in the six memory cells MC connected to a first bitline BL21.

The voltage of the first bitline BL21 may be limited by at least one connection cell connected to the first bitline BL21. Accordingly, consequently, a voltage of first bitline BL21 may be adjusted to a voltage corresponding to an output value of the hidden node HB1 included in the second hidden layer HL1. As described above, when the input voltages VIN1 to VIN3 are applied to the bitlines BL11 to BL13, voltages of the plurality of wordlines WL11 to WL16 and the plurality of bitlines BL21 to BL29 may be adjusted to an equilibrium point by equilibrium propagation.

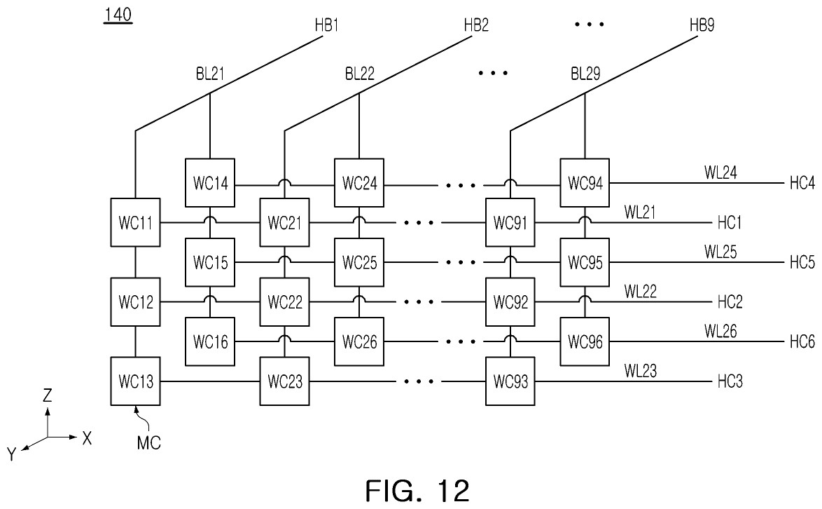

FIG. 12 is a diagram illustrating a third cell region 140 included in a semiconductor device according to one or more example embodiments. The third cell region 140 may include a plurality of memory cells MC, and the plurality of memory cells MC may be arranged in a three-dimensional form in the first direction (e.g., Z-axis direction), the second direction (e.g., X-axis direction) and the third direction (e.g., Y-axis direction).

In one or more example embodiments, each of the plurality of memory cells MC may include a pair of electrode layers and a phase change material layer disposed therebetween. Among a pair of electrode layers, the vertical electrode layer may be connected to one of the plurality of bitlines BL21 to BL29, and the other cell electrode layer may be connected to one of the plurality of wordlines WL22 to WL26.

54 weights WC11 to WC96 assigned to connection paths connecting the second hidden layer HL2 and the third hidden layer HL3 may be stored in the memory cells MC of the third cell region 140. For example, the memory cells MC and the weights WC11 to WC96 may be matched with each other respectively, and one of the 54 weights WC11 to WC96 may be stored in a corresponding memory cell MC.

The third cell region 140 may be arranged in the third direction with respect to the second cell region 130, and may be electrically connected to the second cell region 130 through the plurality of bitlines BL21 to BL29. A connection region including a plurality of connection cells may be disposed between the second cell region 130 and the third cell region 140. Connection cells included in the connection region between the second cell region 130 and the third cell region 140 may be electrically connected to the second cell region 130 and the third cell region 140 through the plurality of bitlines BL21-BL29. Also, a bias voltage for clipping the voltages of the plurality of bitlines BL21-BL29 may be input through wordlines connected to connection cells.

As described with reference to FIG. 11, the voltage of each of the plurality of bitlines BL21 to BL29 may be adjusted to a voltage corresponding to the output values of nine hidden nodes HB1 to HB9 included in the second hidden layer HL2 by equilibrium propagation. Accordingly, by adjusting the voltage of each of the plurality of bitlines BL21 to BL29 by equilibrium propagation, an operation of inputting the output values of the hidden nodes HB1-HB9 of the second hidden layer HL2 to connection paths connecting the second hidden layer HL2 and the third hidden layer HL3 may be executed.

Six weights WC11 to WC16 assigned to six connection paths connected to the first hidden node HB1 of the second hidden layer HL2 may be stored in six memory cells MC connected to the first bitline BL21. Six weights WC21 to WC26 assigned to six connection paths connected to the second hidden node HB2 of the second hidden layer HL2 may be stored in six memory cells MC connected to a second bitline BL22. Weights stored in the memory cells MC connected to the third to ninth bitlines BL23 to BL29 may also be understood by referring to the example described above.

Nine memory cells MC may be connected to each of the plurality of wordlines WL21 to WL26, and the plurality of wordlines WL21 to WL26 may correspond to six hidden nodes HC1-HC6 included in the third hidden layer HL3 of the neural network 100. The weights WC11, WC21, WC31, WC41, WC51, WC61, WC71, WC81, and WC91 assigned to the nine connection paths connecting the first hidden node HC1 of the third hidden layer HL3 to hidden nodes HB1-HB9 of the second hidden layer HL2 may be stored in the nine memory cells MC connected to the first wordline WL21.

The voltage of the first wordline WL21 may be limited by at least one connection cell connected to the first wordline WL21. Accordingly, consequently, the voltage of the first wordline WL21 may be adjusted to a voltage corresponding to an output value of the first hidden node HC1 included in the third hidden layer HL3. When input voltages VIN1 to VIN3 may be applied to the bitlines BL11 to BL13, voltages of the plurality of wordlines WL11 to WL16, the plurality of bitlines BL21 to BL29, and the plurality of wordlines WL21 to WL26 may be adjusted to an equilibrium point by equilibrium propagation.

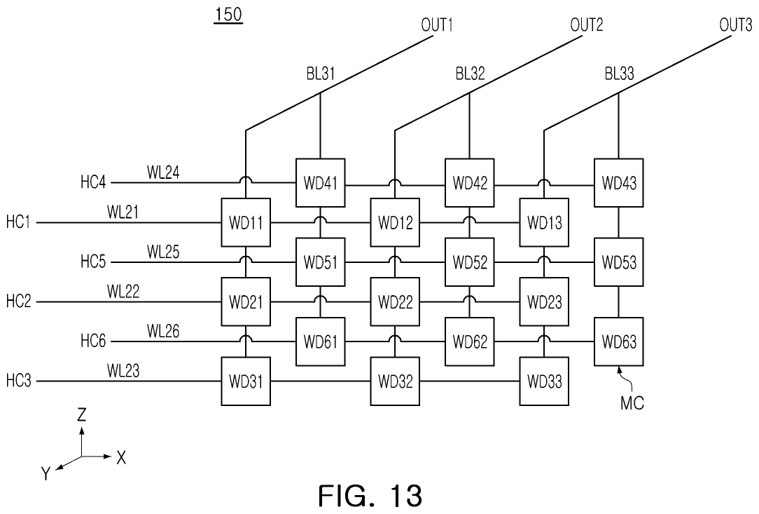

FIG. 13 is a diagram illustrating a fourth cell region 150 included in a semiconductor device according to one or more example embodiments. The fourth cell region 150 may include a plurality of memory cells MC, and the plurality of memory cells MC may be arranged in a three-dimensional form in the first direction (e.g., Z-axis direction), the second direction (e.g., X-axis direction) and the third direction (e.g., Y-axis direction). Each of the plurality of memory cells MC may include a cell electrode layer, a vertical electrode layer, and a phase change material layer disposed therebetween. The vertical electrode layer may be connected to one of the plurality of bitlines BL31 to BL33, and the cell electrode layer may be connected to one of the plurality of wordlines WL22 to WL26.

18 weights WD11 to WD13, WD21 to WD23, WD31 to WD33, WD41 to WD43, WD51 to WD53, and WD61 to WD63 assigned to the connection paths connecting the third hidden layer HL3 to the output layer OL may be stored in the memory cells MC of the fourth cell region 150. For example, the memory cells MC and the weights WD11 to WD63 may be matched with each other respectively, and one of the 18 weights WD11 to WD63 may be stored in a corresponding memory cell MC.

The fourth cell region 150 may be arranged in the second direction with respect to the third cell region 140 and may be electrically connected to the third cell region 140 the plurality of wordlines WL21 to WL26. A connection region including a plurality of connection cells may be disposed between the third cell region 140 and the fourth cell region 150. The connection region between the third cell region 140 and the fourth cell region 150 may have a structure similar to that of the first connection region 120 according to one or more example embodiments described with reference to FIG. 10.

A voltage of each of the plurality of wordlines WL21 to WL26 may be adjusted to a voltage corresponding to each of output values of the six hidden nodes HC1 to HC6 included in the third hidden layer HL3 by equilibrium propagation as described with reference to FIG. 12. Accordingly, an operation of inputting the output values of hidden nodes HC1 to HC6 of the third hidden layer HL3 to connection paths connecting the third hidden layer HL3 to the output layer OL may be implemented by adjusting the voltage of each plurality of wordlines WL21 to WL26 through equilibrium propagation.

Three weights WD11 to WD13 assigned to three connection paths connected to the first hidden node HC1 of the third hidden layer HL3 may be stored in the three memory cells MC connected to the first wordline WL21. Three weights WD21 to WD23 assigned to three connection paths connected to the second hidden node HC2 of the third hidden layer HL3 may be stored in the three memory cells MC connected to the second wordline WL22. The weights stored in the memory cells MC connected to the third to sixth wordlines WL23 to WL26 may also be understood by referring to the example described above.

Six memory cells MC may be connected to each of the plurality of bitlines BL31 to BL33, and the plurality of bitlines BL31 to BL33 may respectively correspond to three output nodes OUT1 to OUT3 included in the output layer OL of the neural network 100. When the input voltages VIN1 to VIN3 are applied to the bitlines BL11 to BL13, voltages of the plurality of wordlines WL11 to WL16, the plurality of bitlines BL21 to BL29, the plurality of wordlines WL21 to WL26, and the plurality of bitlines BL31 to BL33 may be adjusted by an equilibrium point.

The voltages of the plurality of bitlines BL31 to BL33 determined by equilibrium propagation may correspond to the output data of the neural network 100. The voltage detector circuit disposed on the peripheral circuit of the semiconductor device may detect the voltages of the plurality of bitlines BL31 to BL33.

Accordingly, by inputting the input voltage corresponding to the input data to the bitlines BL11 to BL13 connected to the first cell region 110 and detecting the output voltage from the bitlines BL31 to BL33 connected to the fourth cell region 150, neuromorphic computation based on the neural network 100 may be executed. Also, training of the neural network 100 may be performed by imputing the input voltage corresponding to the input data of the training data to the bitlines BL11 to BL13 connected to the first cell region 110, comparing the output voltage detected from the bitlines BL31 to BL33 connected to the fourth cell region 150 with the output data of the training data, and adjusting a resistor value of at least one of the memory cells MC according to the result of comparison.

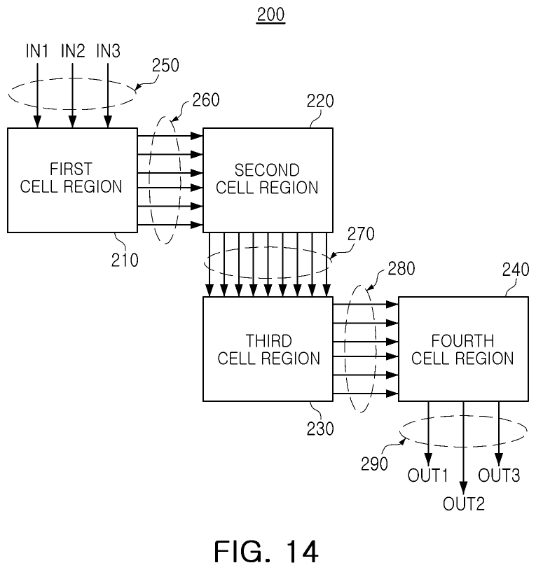

FIG. 14 is a diagram illustrating a structure of a semiconductor device 200 implementing an analog neural network 100. Referring to FIG. 14, the semiconductor device 200 may include first to fourth cell regions 210 to 240, and each of the first to fourth cell regions 210 to 240 may store weights assigned to connection paths between a pair of layers directly connected in the neural network. Although not illustrated in FIG. 14, a connection region in which connection cells are disposed for clipping a level of the output voltage of each of the cell regions 210 to 240 may be disposed between a pair of cell regions 210 to 240 connected to each other.

The first cell region 210 may be connected to a voltage input circuit of the peripheral circuit through first bitlines 250, and the first bitlines 250 may correspond to input nodes IN1 to IN3 of the neural network 100. The first cell region 210 may be connected to the second cell region 220 through first wordlines 260, and the first wordlines 260 may correspond to the first hidden nodes HA1 to HA6 included in the first hidden layer HL1 of the neural network 100.

The second cell region 220 may be connected to the third cell region 230 through second bitlines 270, and the third cell region 230 may be connected to the fourth cell region 240 through second wordlines 280. The second bitlines 270 may correspond to the second hidden nodes HB1 to HB9 included in the second hidden layer HL2 of the neural network 100, and the second wordlines 280 may correspond to the third hidden nodes HC1 to HC6 included in the third hidden layer HL3 of the neural network 100. The fourth cell region 240 may be connected to the voltage detector circuit of the peripheral circuit through third bitlines 290, and the third bitlines 290 may correspond to output nodes OUT1 to OUT3 of the neural network 100.

The training task of the neural network 100 may be performed using training data. When the input voltage corresponding to the input data of the training data is applied to the first bitlines 250, voltages of the third bitlines 290 may be adjusted to an output voltage by equilibrium propagation. A voltage detector circuit may detect the output voltage. In one or more example embodiments, a training task may be performed by adjusting a resistor value of at least one of the memory cells included in the cell regions 210 to 240 according to the result of comparison between the detected output voltage with the output data of the training data until data corresponding to the output voltage matches the output data included in the training data.

Neuromorphic computation based on the neural network 100 may include an inference task obtaining output data by inputting predetermined input data to the neural network 100. In the semiconductor device 200 according to one or more example embodiments, an inference task may be executed by applying an input voltage corresponding to input data to the first bitlines 250 and detecting the output voltage of the third bitlines 290. When the input voltage is applied to the first bitlines 250, the output voltage of the third bitlines 290 may be adjusted by equilibrium propagation without a control operation, neuromorphic computation may be performed swiftly and efficiently.

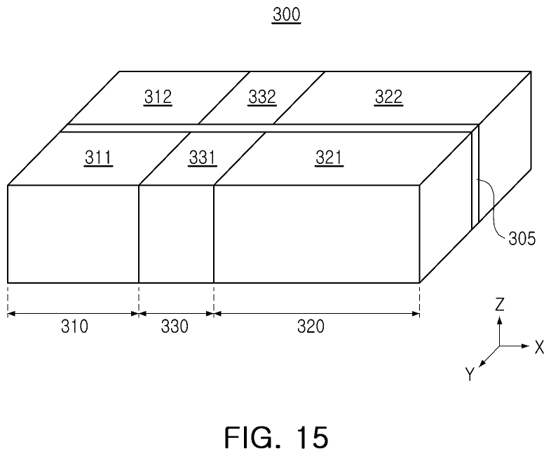

FIG. 15 is a diagram illustrating a semiconductor device according to one or more example embodiments.

Referring to FIG. 15, a semiconductor device 300 according to one or more example embodiments may include a first cell region 310, a second cell region 320, and a first connection region 330 disposed therebetween. Memory cells disposed in the first cell region 310 and the second cell region 320, and connection cells disposed in the first connection region 330 may be arranged in a three-dimensional structure in the first to third directions (e.g., Z-axis, X-axis, and Y-axis directions).

The first cell region 310 may be divided into a plurality of blocks 311 and 312 in the third direction (e.g., Y-axis direction) by an isolation layer 305 extending in the first direction (e.g., Z-axis direction) and the second direction (e.g., X-axis direction). Similarly, the second cell region 320 may also include a plurality of blocks 321 and 322 arranged in the third direction, and the first connection region 330 may also include a plurality of blocks 331 and 332 arranged in the third direction.

In one or more example embodiments illustrated in FIG. 15, the first cell region 310, the second cell region 320 and the connection region 330 may share a plurality of horizontal electrode layers stacked in the first direction and may extend in the second direction. Also, horizontal electrode layers disposed on a specific level in the first direction may be isolated from each other in the third direction by the isolation layer 305. For example, a horizontal electrode layer disposed on a first level in the first direction may extend in the second direction from the first blocks 311, 321, and 331, and another horizontal electrode layer disposed on the first level may extend in the second direction from the second blocks 312, 322, and 332.

In this way, by separating the first blocks 311, 321, 331 and the second blocks 312, 322, 332 in the third direction using the isolation layer 305, a resistor value of each of memory cells may be individually adjusted. Accordingly, by accessing each memory cell individually, the weight determined as a result of the training of the neural network may be stored, and the semiconductor device 300 may efficiently support neuromorphic computation.

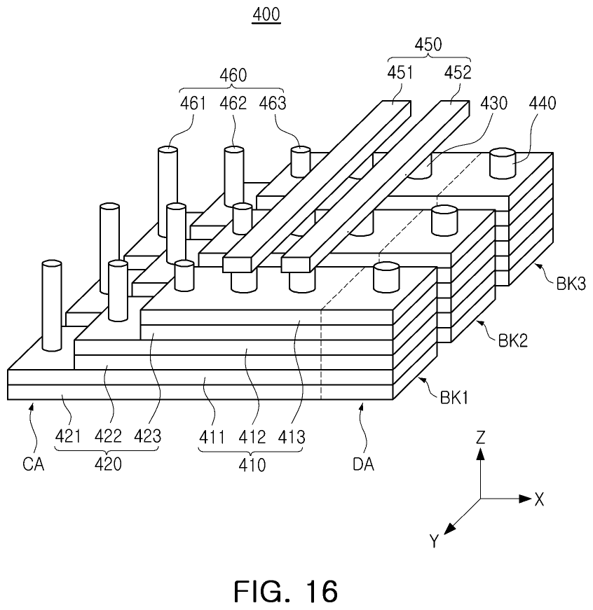

FIG. 16 is a diagram illustrating a semiconductor device according to one or more example embodiments.

FIG. 16 is a perspective diagram illustrating a structure of a cell region CA and a connection region DA included in a semiconductor device 400 according to one or more example embodiments. Referring to FIG. 16, the cell region CA and the connection region DA may include a plurality of horizontal electrode layers 411 to 413 (collectively, 410) and a plurality of insulating layers 421 to 423 (collectively, 420) stacked alternately in the first direction (e.g., Z-axis direction). The cell region CA and the connection region DA may be divided into a plurality of blocks BK1 to BK3. In one or more example embodiments, the number of the plurality of horizontal electrode layers 410 may be smaller than the number of the plurality of insulating layers 420. For example, at least one insulating layer may be additionally disposed above an uppermost horizontal electrode layer 413.

In one or more example embodiments, the plurality of horizontal electrode layers 410 may extend to different lengths in the second direction (e.g., X-axis direction) and may form a staircase structure as illustrated in FIG. 16. The plurality of horizontal electrode layers 410 may be paired with the plurality of insulating layers 420 and may extend to different lengths in the second direction and may form a staircase structure. Accordingly, at least a portion region of each of the plurality of horizontal electrode layers 410 may be exposed in the second direction, and the plurality of wordline contacts 461 to 463 (collectively, 460) may be connected to the plurality of horizontal electrode layers 410.

A plurality of vertical structures 430 extending in the first direction and penetrating the plurality of horizontal electrode layers 410 may be disposed in the cell region CA. Each of the plurality of vertical structures 430 may include a vertical electrode layer extending in the first direction and a phase change material layer surrounding the vertical electrode layer, and the vertical electrode layer may be connected to the plurality of bitlines 451 to 452 (collectively, 450).

The plurality of bitlines 450 may extend in the third direction (e.g., Y-axis direction) and may be commonly connected to two or more vertical structures 430 disposed in the same position in the second direction and disposed in different blocks BK1 to BK3. Since the plurality of horizontal electrode layers 410 disposed in different blocks BK1 to BK3 are connected to different wordline contacts 460, each of memory cells disposed in the cell region CA may be individually controlled. For example, to change a resistor value of each of three memory cells included in the first block BK1 and connected to a first bitline 451, a predetermined bias voltage may be input to each of the wordline contacts 460 connected to the first block BK1. In this case, by appropriately determining a voltage of a second bitline 452, a resistor value of each of three memory cells included in the first block BK1 and connected to the second bitline 452 may be prevented from being changed together.

The vertical electrode layer included in each of the plurality of vertical structures 430 may include the same conductive material as that of the horizontal electrode layers 410. In example embodiments, the vertical electrode layer and the horizontal electrode layers 410 may include the same material or may include different materials. For example, the vertical electrode layer and the horizontal electrode layers 410 may include a material such as a metal compound and/or a metal. The phase change material layer may include, for example, at least one of a Ge-Sb-Te (GST) series material, In-Sb-Te (IST) series material, Bi-Sb-Te (BST) series material, and GeTe-SbTe superlattice.

A plurality of pillar structures 440 extending in the first direction and penetrating the plurality of horizontal electrode layers 410 may be disposed in the connection region DA. Each of the plurality of pillar structures 440 may include a bias electrode layer extending in the first direction and a switching material layer surrounding the bias electrode layer. Similarly to the vertical electrode layer, the bias electrode layer may include the same material as that of the horizontal electrode layers 410 or may include different materials. The switching material layer may include an ovonic threshold switch (OTS) material, and the OTS material may include, for example, Ge, Si, As, Te, and/or the like.

In one or more example embodiments illustrated in FIG. 16, when the memory cells of the cell region CA store weights assigned to connection paths between an input layer and a first hidden layer of the neural network, the bitlines 450 may be connected to the voltage input circuit. Also, to record weights by changing a resistor value of each of the memory cells, wordline contacts 460 may also be connected to a circuit for applying a voltage.

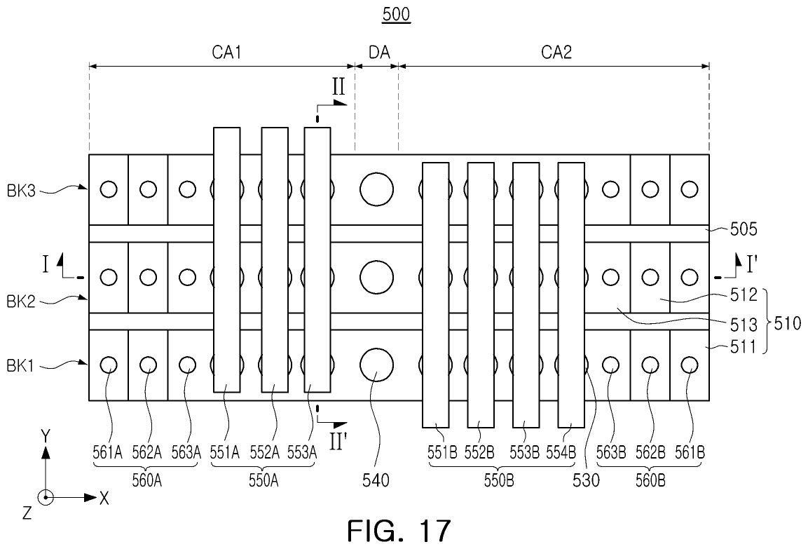

FIGS. 17 to 19 are diagrams illustrating a semiconductor device according to one or more example embodiments.

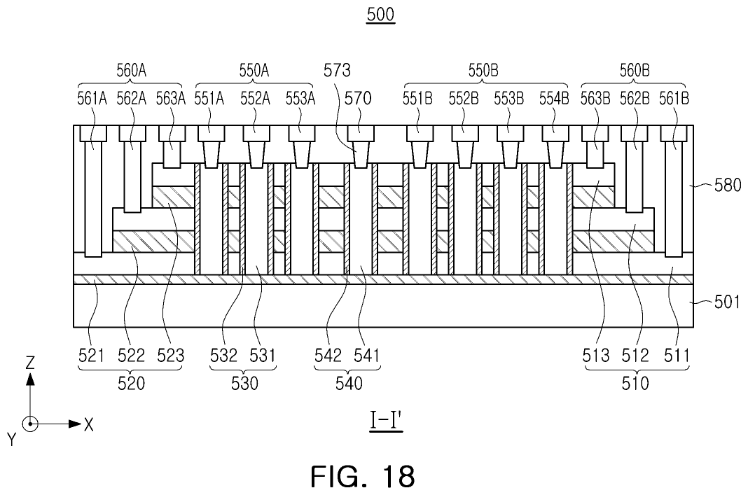

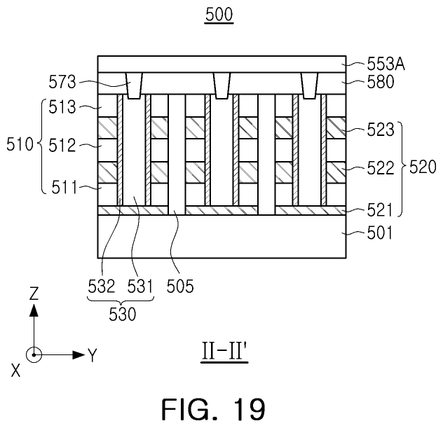

FIG. 17 is a diagram illustrating a portion of regions of a semiconductor device 500 according to one or more example embodiments. FIG. 18 is a cross-sectional diagram taken along line I-I′ in FIG. 17. FIG. 19 is a cross-sectional diagram taken along line II-II′ in FIG. 17.

Referring to FIGS. 17 to 19, a semiconductor device 500 according to one or more example embodiments may include a plurality of horizontal electrode layers 511 to 513 (collectively, 510) and a plurality of insulating layers 521 to 523 (collectively, 520) stacked on a substrate 501 in the first direction (e.g., Z-axis direction) perpendicular to an upper surface of substrate 501. The plurality of horizontal electrode layers 510 and the plurality of insulating layers 520 may be alternately stacked and may extend in the second direction (e.g., X-axis direction) parallel to the upper surface of the substrate 501.

The semiconductor device 500 may include cell regions CA1 and CA2 and a connection region DA disposed in the second direction. For example, the connection region DA may be defined between a first cell region CA1 and a second cell region CA2. The plurality of horizontal electrode layers 510 and the plurality of insulating layers 520 may extend in the second direction through the first cell region CA1, the connection region DA and the second cell region CA2. For example, in each of the plurality of horizontal electrode layers 510, a region disposed in the first cell region CA1 and the second cell region CA2 may be defined as a cell electrode layer, and a region disposed in the connection region DA may be defined as a connection electrode layer.

A plurality of vertical structures 530 extending in the first direction and penetrating the plurality of horizontal electrode layers 510 may be disposed in the first cell region CA1 and the second cell region CA2. As illustrated in FIGS. 18 and 19, each of the plurality of vertical structures 530 may include a vertical electrode layer 531 and a phase change material layer 532 surrounding the vertical electrode layer 531. Accordingly, in the second direction (e.g., X-axis direction) and the third direction (e.g., Y-axis direction), the phase change material layer 532 may be disposed between the vertical electrode layer 531 and the plurality of horizontal electrode layers 510. By the plurality of horizontal electrode layers 510 and the plurality of vertical structures 530, the plurality of memory cells arranged in the first to third directions may be provided in the first cell region CA1 and the second cell region CA2. In the example embodiment illustrated in FIGS. 17 to 19, the number of memory cells included in the first cell region CA1 may be different from the number of memory cells included in the second cell region CA2.

A plurality of pillar structures 540 may be disposed in the connection region DA. The plurality of pillar structures 540 may include a bias electrode layer 541 and a switching material layer 542 surrounding the bias electrode layer 541. A plurality of connection cells arranged in the first to third directions by the plurality of horizontal electrode layers 510 and the plurality of pillar structures 540 may be provided in the connection region DA.

The plurality of horizontal electrode layers 510 and the plurality of insulating layers 520 may be divided into a plurality of blocks BK1 to BK3 by isolation layers 505 extending in the first direction and arranged in the third direction. The plurality of blocks BK1 to BK3 may be defined as a region between a pair of isolation layers 505 adjacent to each other in the third direction, and as illustrated in FIGS. 17 and 19, in each of the plurality of blocks BK1 to BK3, the plurality of vertical structures 530 may be arranged linearly in the second direction.

The plurality of horizontal electrode layers 510 may extend to different lengths and may form a staircase structure as illustrated in FIG. 18 in the second direction. The plurality of horizontal electrode layers 510 may form a pair with the plurality of insulating layers 520, may extend to different lengths in the second direction and may form a staircase structure. Accordingly, as illustrated in FIGS. 17 and 18, the plurality of horizontal electrode layers 510 may be connected to a plurality of wordline contacts 561A to 563A (collectively, 560A), 561B to 563B (collectively, 560B) in different positions in the second direction.

In example embodiments, the plurality of horizontal electrode layers 510 may extend to different lengths only on one side of the second direction and may form a staircase structure. In this case, the plurality of wordline contacts 560A and 560B may also be disposed only on one side of the second direction and may be connected to the plurality of horizontal electrode layers 510.

The plurality of vertical structures 530 may be connected to the plurality of bitlines 551A to 553A (collectively, 550A), 551B to 553B (collectively, 550B) extending in the third direction. The plurality of bitlines 550A and 550B may be connected to the plurality of vertical structures 530 through a plurality of contacts 573.

For example, two or more vertical structures 530 disposed in the same position in the second direction, disposed one by one in different blocks BK1 to BK3 and arranged in the third direction may be commonly connected to one of the plurality of bitlines 550A and 550B. In one or more example embodiments illustrated in FIGS. 17 and 19, three vertical structures 530 disposed in one position in the second direction may be commonly connected to one of the plurality of bitlines 550A and 550B.

Two or more vertical structures 530 commonly connected to one of the plurality of bitlines 550A and 550B may penetrate the plurality of horizontal electrode layers 510 in different blocks BK1 to BK3. Accordingly, the memory cells included in the plurality of blocks BK1 to BK3 may be individually controlled.

For example, in the case of the first block BK1, nine memory cells may be disposed in the first cell region CA1 and 12 memory cells may be disposed in the second cell region CA2. By inputting a program voltage to the first horizontal electrode layer 511 and the first bitline 551A of the first cell region CA1, a resistor value of one of memory cells provided by the vertical structure 530 connected to the first bitline 551A and the first horizontal electrode layer 511 may be individually may be adjusted. In the semiconductor device 500 according to one or more example embodiments, the resistor value of each of the memory cells may be independently adjusted to execute a training task and an inference task of the neural network as described above.

The voltage input to each of the plurality of horizontal electrode layers 510 may be applied through the plurality of wordline contacts 560A and 560B. For example, the plurality of wordline contacts 560A and 560B may be connected to a plurality of metal wirings 570 disposed on the same level as a level of the plurality of bitlines 550A and 550B. The plurality of bitlines 550A and 550B, the plurality of metal wirings 570, and the plurality of contacts 573 may be formed in an interlayer insulating layer 580.

The plurality of pillar structures 540 may be connected to the plurality of metal wirings 570 through the plurality of contacts 573. The bias electrode layer 541 included in each of the plurality of pillar structures 540 may be connected to a metal wiring 570 through a contact 573, and a predetermined bias voltage may be input to the bias electrode layer 541 while the training task and the inference task are executed. Due to the bias voltage input to the bias electrode layer 541 and the switching material layer 542 including an OTS material, the connection cells provided by the plurality of horizontal electrode layers 510 and the plurality of pillar structures 540 may operate as an OTS element having electrical properties similarly to diodes.

Assuming an inference task of executing neuromorphic computation based on a neural network, input voltages applied through the plurality of bitlines 550A may correspond to pieces of input data. Each of the memory cells included in the first cell region CA1 and the second cell region CA2 may store weights given to the connection path connecting nodes in the trained neural network in a form of a resistor value.

For example, the first cell region CA1 may store weights given to connection paths between input nodes and first hidden nodes, and the second cell region CA2 may store weights assigned to the connection paths between the first hidden nodes and the second hidden nodes. When input voltages are applied through the plurality of bitlines 550A, the voltage of each of the plurality of horizontal electrode layers 510 may be adjusted to a voltage corresponding to an output value of each of the first hidden nodes by equilibrium propagation. The voltage of each of the plurality of horizontal electrode layers 510 may be clipped by the connection cells 540 to not exceed a predetermined upper and/or lower limit voltage.

The four memory cells provided by the first horizontal electrode layer 510 of first block BK1 may store weights given to the connection paths connecting one of the first hidden nodes to the second hidden nodes. Accordingly, by equilibrium propagation based on a resistor value of each memory cell of the second cell region CA2, a voltage of each of the plurality of bitlines 550B in the second cell region CA2 may be adjusted to a voltage corresponding to an output value of each of the second hidden nodes. By the plurality of bitlines 550B, the voltage corresponding to the output value of each of the second hidden nodes may be transferred to another cell region adjacent to the second cell region CA2.

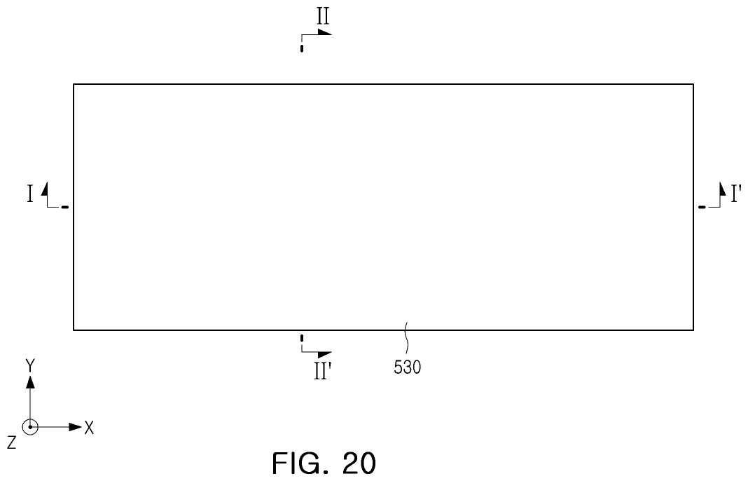

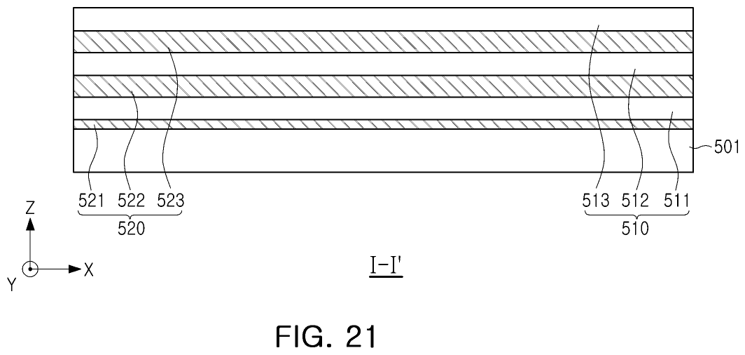

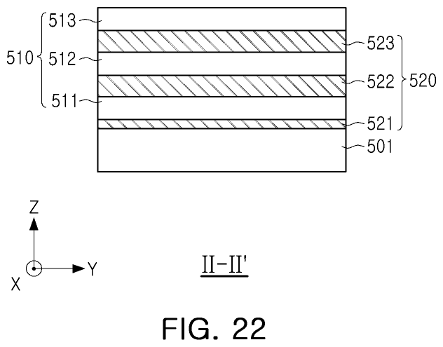

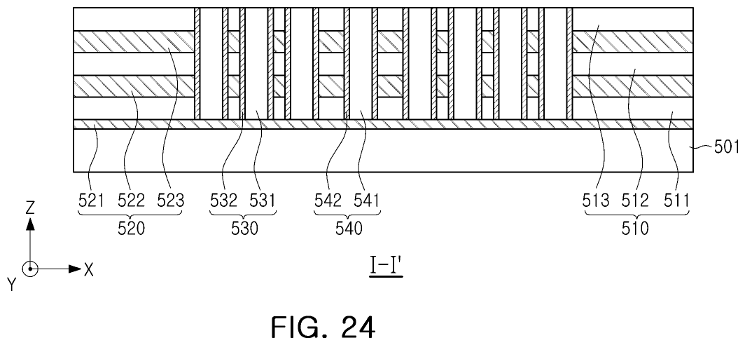

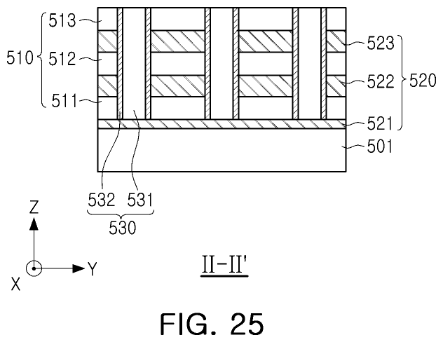

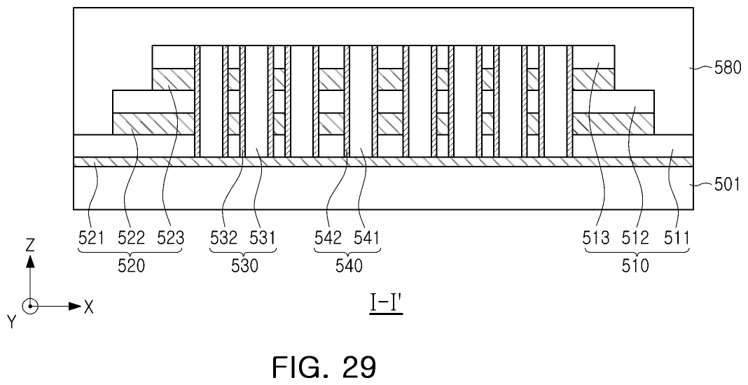

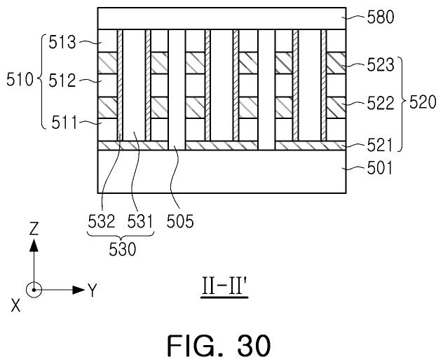

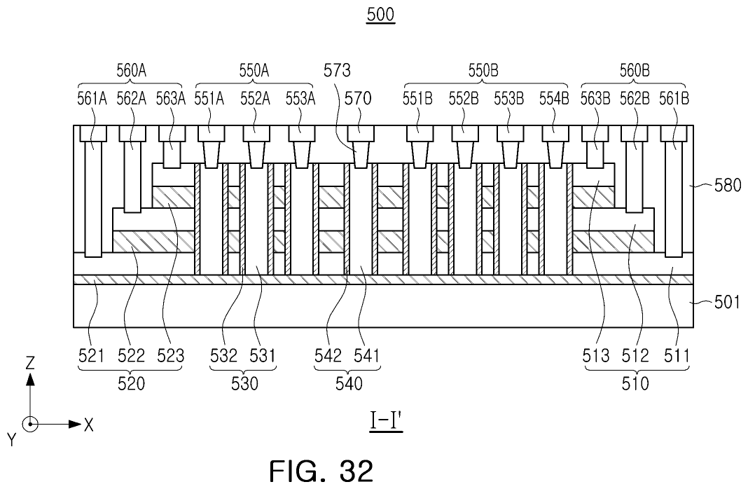

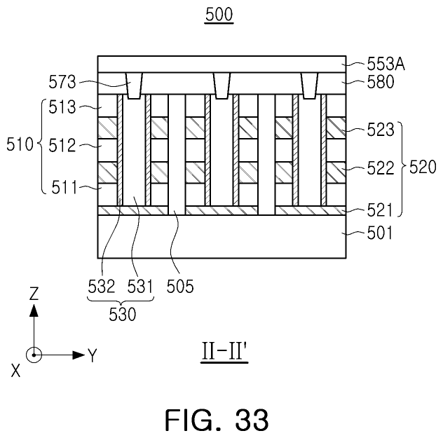

FIGS. 20 to 33 are diagrams illustrating a method of manufacturing a semiconductor device according to one or more example embodiments.

First, referring to FIGS. 20 to 22, a plurality of horizontal electrode layers 510 and a plurality of insulating layers 520 may be alternately stacked on the substrate 501 in the first direction (e.g., Z-axis direction) perpendicular to an upper surface of the substrate 501. The plurality of horizontal electrode layers 510 may include a conductive material such as a metal and/or a metal compound, and the plurality of insulating layers 520 may include an insulating material. For example, the plurality of horizontal electrode layers 510 may include tungsten, titanium nitride, and/or the like, and the plurality of insulating layers 520 may include silicon oxide, silicon nitride, silicon oxynitride, and/or the like. In one or more example embodiments, each of the plurality of horizontal electrode layers 510 may have a thickness of 10 nm or more and 50 nm or less.

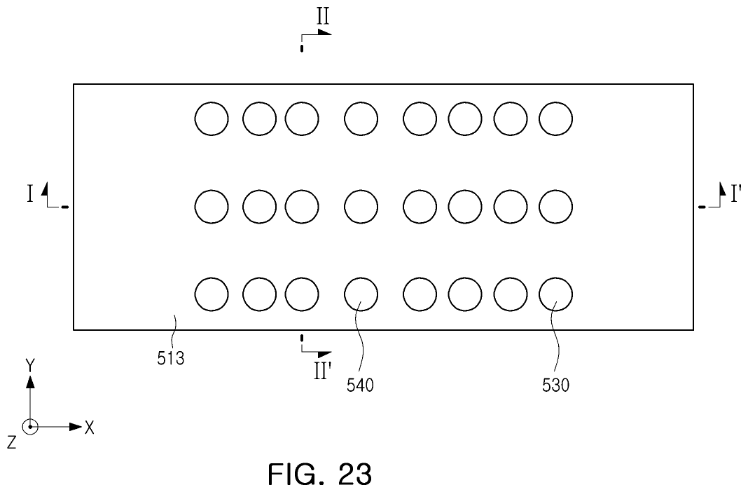

Thereafter, referring to FIGS. 23 to 25, a plurality of vertical structures 530 and a plurality of pillar structures 540 may be formed. The process of forming the plurality of vertical structures 530 and the plurality of pillar structures 540 may start with the process of forming a plurality of holes extending in the first direction perpendicular to the upper surface of the substrate 501. When the plurality of holes are formed, a phase change material layer 532 may be formed on an internal sidewall of holes corresponding to the plurality of vertical structures 530 while holes corresponding to the plurality of pillar structures 540 are covered. The phase change material layer may include, for example, at least one of a Ge-Sb-Te (GST) series material, In-Sb-Te (IST) series material, Bi-Sb-Te (BST) series material and GeTe-Sb Te superlattice.

Thereafter, a switching material layer 531 may be formed on an internal sidewall of the holes corresponding to the plurality of pillar structures 540 while the holes corresponding to the plurality of vertical structures 530 are covered. The switching material layer 542 may include an OTS material. When the phase change material layer 532 and the switching material layer 542 are formed, a vertical electrode layer 531 and a bias electrode layer 541 may be formed using a conductive material in the phase change material layer 532 and the switching material layer 542, respectively, in the plurality of holes. In one or more example embodiments, the vertical electrode layer 531 and the bias electrode layer 541 may include the same material, and may include the same material as that of the horizontal electrode layers 510. However, at least a portion of the vertical electrode layer 531, the bias electrode layer 541, and the horizontal electrode layers 510 may include different materials.

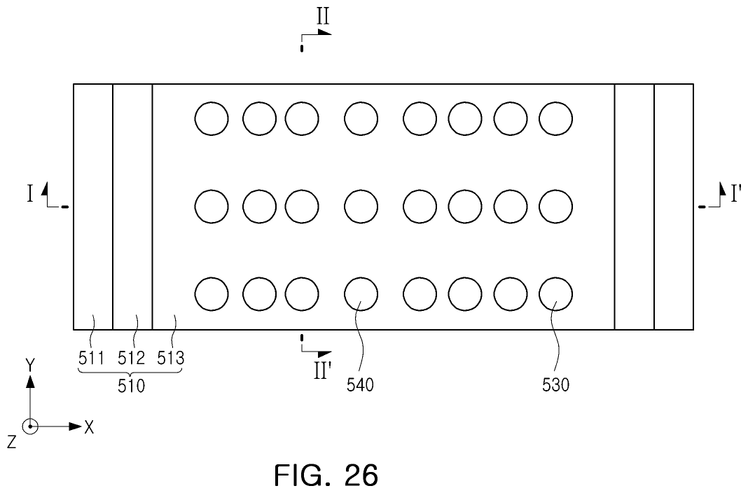

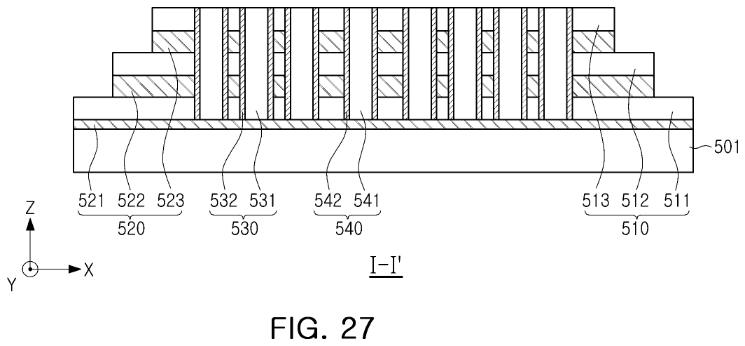

Thereafter, referring to FIGS. 26 and 27, a process of etching the plurality of horizontal electrode layers 510 and the plurality of insulating layers 520 to have different lengths in the second direction may be performed. For example, a reactive ion etching (RIE) process may be applied to the process of forming plurality of holes, to form the plurality of vertical structures 530 and the plurality of pillar structures 540, and may be applied to the process of etching the plurality of horizontal electrode layers 510 and the plurality of insulating layers 520. Accordingly, as illustrated in FIGS. 26 and 27, at least on one side of the second direction, a staircase structure may be formed by the plurality of horizontal electrode layers 510 and the plurality of insulating layers 520, and in each of the plurality of horizontal electrode layers 510, at least a portion of regions may be exposed.

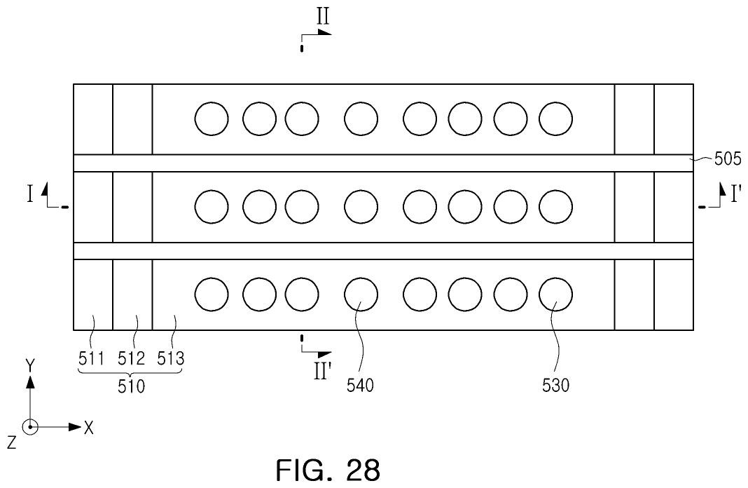

Referring to FIGS. 28 to 30, an interlayer insulating layer 580 may be formed on the plurality of horizontal electrode layers 510. The interlayer insulating layer 580 may be formed of an insulating material such as silicon oxide, silicon nitride, or silicon oxynitride. When the interlayer insulating layer 580 is formed, a plurality of isolation layers 505 extending in the first and second directions and arranged in the third directions may be formed. The plurality of horizontal electrode layers 510 may be isolated from each other in the third direction by the plurality of isolation layers 505, and thus the plurality of blocks may be defined.

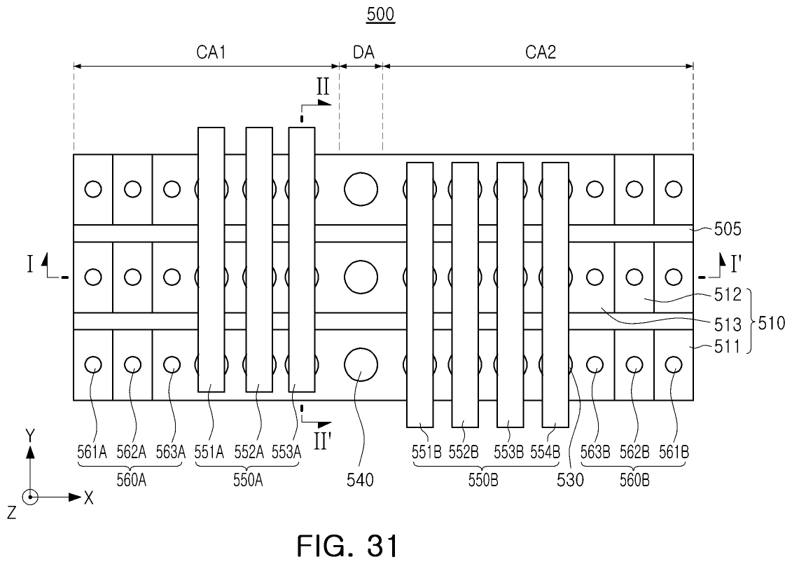

Referring to FIGS. 31 to 33, wiring patterns 570 connected to the plurality of horizontal electrode layers 510, the plurality of vertical electrode layers 531, and the plurality of bias electrode layers 541 may be formed. Among the wiring patterns 570, a portion connected to the plurality of vertical electrode layers 531 may be defined as a plurality of bitlines 551A to 553A (collectively, 550A) and 551B to 553B (collectively, 550B). The plurality of horizontal electrode layers 510 may be connected to the wiring patterns 570 through the plurality of wordline contacts 561A to 563A (collectively, 560A), 561B to 563B (collectively, 560B).

A portion of the wiring patterns 570 connected to the plurality of wordline contacts 560A and 560B may function as wordlines. Accordingly, wiring patterns providing the plurality of wordlines and the plurality of bitlines 550A and 550B may be disposed on memory cells in the first direction.

The plurality of bitlines 550A and 550B may extend in the third direction parallel to the upper surface of the substrate 501, may be disposed in different blocks, and may connect two or more horizontal electrode layers 510 disposed in the same position in the second direction to each other. Two or more horizontal electrode layers 510 commonly connected to one of the plurality of bitlines 550A and 550B may be isolated from each other by the plurality of isolation layers 505, may be coupled to the horizontal electrode layers 510 disposed in different blocks and may provide memory cells. Accordingly, the plurality of memory cells may be individually controlled.

In example embodiments, the order of the manufacturing processes described with reference to FIGS. 20 to 33 may vary. For example, as described with reference to FIGS. 23 to 25, the process of forming the plurality of vertical structures 530 and the plurality of pillar structures 540 may be performed subsequently to the process of forming the staircase structure by etching the plurality of horizontal electrode layers 510.

According to the aforementioned example embodiments, a plurality of memory cells may be implemented with horizontal electrode layers stacked on a substrate, vertical electrode layers penetrating the horizontal electrode layers, and phase change material layers, and weights assigned to connection paths between nodes in a neural network may be stored in the plurality of memory cells. In one or more example embodiments, neuromorphic computation based on a neural network may be performed simply by supplying an input voltage corresponding to input data to at least a portion of the horizontal electrode layers and the vertical electrode layers, and accordingly, a semiconductor device supporting neuromorphic computation may be implemented without a complicated peripheral circuit.

While the example embodiments have been illustrated and described above, it will be configured as apparent to those skilled in the art that modifications and variations may be made without departing from the scope in the example embodiment as defined by the appended claims.

1. A semiconductor device, comprising:
a plurality of horizontal electrode layers stacked in a first direction perpendicular to an upper surface of a substrate;
a plurality of vertical structures extending in the first direction, penetrating the plurality of horizontal electrode layers and arranged in a second direction and a third direction, the second direction and the third direction being parallel to the upper surface of the substrate and intersecting each other; and
a plurality of bitlines electrically connected to the plurality of vertical structures in the first direction,
wherein each of the plurality of vertical structures includes a vertical electrode layer having a pillar shape extending in the first direction, and a phase change material layer extending in the first direction and disposed between the vertical electrode layer and the plurality of horizontal electrode layers in the second direction and the third direction.

2. The semiconductor device of claim 1, further comprising:
a plurality of isolation layers extending in the first direction and the second direction and dividing the plurality of horizontal electrode layers into a plurality of unit blocks,
wherein the plurality of bitlines extend in the third direction.

3. The semiconductor device of claim 2, wherein the plurality of isolation layers are arranged in the third direction, and the plurality of vertical structures are arranged in the second direction respectively between pairs of isolation layers adjacent to each other in the third direction.

4. The semiconductor device of claim 3, wherein the plurality of vertical structures are disposed one by one in the third direction between a corresponding pair of isolation layers.

5. The semiconductor device of claim 3, wherein two or more of the plurality of vertical structures, disposed in a same position in the second direction, are commonly and electrically connected to one of the plurality of bitlines.

6. The semiconductor device of claim 2, further comprising:
a plurality of wordlines electrically connected to the plurality of horizontal electrode layers in a region in which the plurality of horizontal electrode layers extend to different lengths in the second direction.

7. The semiconductor device of claim 1, wherein the plurality of horizontal electrode layers and the plurality of vertical structures provide a plurality of memory cells, and data is stored by controlling a resistance of the phase change material layer according to a bias voltage applied to each of the plurality of horizontal electrode layers and the plurality of vertical structures.

8. The semiconductor device of claim 1, further comprising:
a plurality of insulating layers alternately stacked with the plurality of horizontal electrode layers in the first direction.

9. The semiconductor device of claim 1, wherein the plurality of horizontal electrode layers and the vertical electrode layer include a same material.

10. The semiconductor device of claim 1, wherein a thickness of each of the plurality of horizontal electrode layers is 10 nm or more and 50 nm or less.

11. A semiconductor device, comprising:
a plurality of cell regions each including a plurality of memory cells, the plurality of memory cells being arranged in a first direction perpendicular to an upper surface of a substrate, and arranged in a second direction and a third direction parallel to the upper surface of the substrate and intersecting each other, the plurality of memory cells being disposed in different positions in at least one of the second direction or the third direction; and
at least one connection region disposed between the plurality of cell regions,
wherein each of the plurality of cell regions includes a plurality of cell electrode layers stacked in the first direction, and a plurality of vertical structures extending in the first direction and penetrating the plurality of cell electrode layers, each of the plurality of vertical structures including a vertical electrode layer and a phase change material layer surrounding the vertical electrode layer, and
wherein a connection region of the at least one connection region includes a plurality of connection electrode layers stacked in the first direction and electrically connected to the plurality of cell electrode layers, and a plurality of pillar structures extending in the first direction and penetrating the plurality of connection electrode layers, each of the plurality of pillar structures including a bias electrode layer and a switching material layer surrounding the bias electrode layer.

12. The semiconductor device of claim 11, wherein the plurality of cell regions include a first cell region and a second cell region in different positions in the second direction, and
wherein the connection region includes a first connection region between the first cell region and the second cell region in the second direction.

13. The semiconductor device of claim 12, wherein the plurality of cell electrode layers and the plurality of connection electrode layers extend in the second direction, and
wherein a cell electrode layer and a connection electrode layer disposed on a same level in the first direction are electrically connected to each other.

14. The semiconductor device of claim 13, further comprising:
a plurality of bitlines extending in the third direction,
wherein bitlines of a first group among the plurality of bitlines are electrically connected to the plurality of vertical structures included in the first cell region, and bitlines of a second group among the plurality of bitlines are electrically connected to the plurality of vertical structures included in the second cell region.

15. The semiconductor device of claim 11, wherein the phase change material layer and the switching material layer include different materials.

16. A semiconductor device supporting computation based on a neural network including a plurality of layers, the semiconductor device comprising:
a memory cell array including a plurality of cell regions, wherein each of the plurality of cell regions include a plurality of memory cells formed on a substrate; and
a peripheral circuit including a voltage input circuit and a voltage detector circuit, the voltage input circuit being configured to input an input voltage corresponding to input data of the neural network to the memory cell array, and the voltage detector circuit being configured to read an output voltage corresponding to output data of the neural network from the memory cell array,
wherein, in the neural network, weights corresponding to connection paths connecting first nodes of a first layer and second nodes of a second layer, are stored in the plurality of memory cells disposed in a first cell region among the plurality of cell regions,
wherein the first layer and the second layer are disposed consecutively,
wherein input voltages corresponding to data of the first nodes are input to the first cell region through first lines electrically connected to the first cell region, and output voltages corresponding to data of the second nodes are transferred to a second cell region adjacent to the first cell region through second lines electrically connected to the first cell region, and
wherein the first lines and the second lines extend in different directions.

17. The semiconductor device of claim 16, wherein, in each of the plurality of cell regions, the plurality of memory cells are arranged in a three-dimensional form in a first direction perpendicular to an upper surface of the substrate, and in a second direction and a third direction parallel to the upper surface of the substrate.

18. The semiconductor device of claim 17, wherein the first lines extend in the third direction and the second lines extend in the second direction, and
wherein the first cell region and the second cell region are arranged in the second direction.

19. The semiconductor device of claim 18, further comprising:
a connection region disposed between the first cell region and the second cell region in the second direction, and including a plurality of ovonic threshold switch (OTS) elements configured to limit a magnitude of the output voltages.

20. The semiconductor device of claim 16, wherein the first lines are disposed above the plurality of memory cells in a first direction perpendicular to an upper surface of the substrate.

21-23. (canceled)
